(19) United States
(12) Patent Application Publication
(10) Pub. No.: US 2010/0154712 A1
(43) Pub. Date: Jun. 24, 2010

(54) SOURCE GAS GENERATING DEVICE AND FILM FORMING APPARATUS

(75) Inventors: Akitake Tamura, Nirasaki (JP); Teruyuki Hayashi, Sendai (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/639,410

(22) Filed: Dec. 16, 2009

(30) Foreign Application Priority Data
Dec. 18, 2008 (JP) 2008-322852

(51) Int. Cl. C23C 16/00

(52) U.S. Cl. 118/726

(57) ABSTRACT

A source gas generating device includes a liquid accommodation unit that accommodates therein the liquid source obtained by liquefying the solid source; a first energy feed unit that supplies energy to raise a temperature of a first region within the liquid accommodation unit to a melting point of the solid source; a second energy feed unit that supplies energy to raise a temperature of a second region within the liquid accommodation unit to a temperature higher than the temperature of the first region, the second region being distanced apart from the first region via a liquid flowing region; a solid source feed unit that supplies the solid source into the first region of the liquid accommodation unit; and an outlet port that discharges the source gas produced by the evaporation of the liquid source within the second region of the liquid accommodation unit.

### CROSS-REFERENCE TO RELATED APPLICATION

This application claims the benefit of Japanese Patent Application No. 2008-322852, filed on Dec. 18, 2008, the entire disclosures of which are incorporated herein by reference.

### FIELD OF THE INVENTION

The present disclosure relates to a source gas generating device that generates a film forming source gas by vaporizing a liquid source produced by liquefying a solid source, and also relates to a film forming apparatus that performs a film forming process by supplying the source gas onto a substrate.

### BACKGROUND OF THE INVENTION

Along with a liquid crystal display, an organic EL (Electro Luminescence) display using an organic EL material is known as an image display device for use in a FPD (flat panel display) or a cellular phone, for example. In a manufacturing process of such an organic EL display, a source gas is produced through evaporation or sublimation by way of heating a solid source, e.g., an organic EL material containing organic compounds, and a thin film is formed by solidifying the source gas on, e.g., a glass substrate.

For example, in order to form a film of the organic EL material by producing the source gas through evaporation, a powdered solid source such as an alumiquinolinol complex, a low-molecular-weight aryl amine derivative or an iridium complex is accommodated in a source container. Then, the solid source is heated and melted at a temperature of, e.g., about 300° C. so as to obtain a liquid source, and a carrier gas such as an argon (Ar) gas is flown into the source container. Then, a source gas evaporated from a surface of the liquid source and the carrier gas are supplied onto a substrate, which is mounted on a mounting table within a processing chamber under a vacuum atmosphere, as a processing gas. Within the processing chamber, the source gas is adsorbed and solidified on the substrate, and, thus, a thin film is formed thereon. In this case, if a heating temperature within the source container is too high, degradation or deterioration of the source may occur. In contrast, if the heating temperature is too low, a concentration of the source gas in the processing gas may decrease, resulting in a decrease of a film forming rate. Therefore, the heating temperature in the source container is set to be as high as possible within an allowable range where any conspicuous degradation of the source is not caused.

Further, in order to uniform thin film thicknesses between substrates on which film formation is performed, the concentration of the source gas in the processing gas supplied into the processing chamber is maintained constant, for example. To be specific, a temperature is precisely controlled so as to regulate the heating temperature of the liquid source at the above-mentioned temperature, to thereby uniform the amount of the source gas evaporated from the liquid source.

When the amount of the liquid source in the source container is decreased after being used in the film forming process, the source gas needs to be replenished into the source container, e.g., every time a film forming process on a preset number of substrates is performed. In this case, the liquid source in the source container is heated and maintained at the high temperature as described above, whereas the solid source has, e.g., a normal temperature, lower than the temperature of the liquid source. Thus, if the low-temperature solid source is supplied into the source container during the film forming process, the temperature of the liquid source is likely to decrease, causing a decrease of the amount of the source gas to be supplied into the processing chamber. Accordingly, for example, after the film forming process is performed on the preset number of substrates, the source container is opened to the atmosphere, and the film forming process is resumed after the solid source is replenished into the source container. If, however, the solid source is replenished in such a batch type manner, the film forming process should be interrupted. Thus, in order to improve throughput, the frequency of the replenishment of the solid source needs to be reduced.

However, in order to reduce the frequency of the replenishment of the solid source, it is necessary to increase the storage amount of the liquid source. In such a case, however, since the liquid source is heated at a high temperature for a long time, degradation or deterioration of the liquid source may occur. Further, if the storage amount of the liquid source is increased, a surface level of the liquid source is slowly lowered as the film forming process progresses. Accordingly, a stagnant space of the source gas within the source container increases. As a result, the generated source gas may be concentrated in, e.g., a lower region of the stagnant space, resulting in a failure to mix the source gas with the carrier gas and a variation of the concentration of the source gas to be supplied into the processing chamber. In contrast, if the amount of the liquid source in the source container is reduced in order to suppress degradation or deterioration by heating, the frequency of the replenishment of the solid source increases, resulting in deterioration of throughput. Furthermore, if the source container is frequently opened to the atmosphere in order to replenish the solid source into the source container, it is highly likely that moisture in the atmosphere may enter the processing chamber. In such a case, it takes a great amount of time to evacuate the processing chamber and resume the film forming process.

As a demand for the organic EL film increases, it is required to provide a technique capable of suppressing thermal degradation or deterioration of the source during the organic EL film forming process and capable of obtaining the source gas stably for a long time. Further, since the amount of the source gas necessary for the film forming process increases due to the scale-up of the substrate, such a technique is highly required.

Patent Document 1 discloses a technique in which powder of an organic material is held on an endless belt 30 and transferred, and a film of the organic material is deposited on a surface of a base body 60 held to face the endless belt 30. However, if the powder is held on the endless belt 30 in such a way, it is required to vaporize the total amount of the powder at once. Therefore, there is a high risk of thermal degradation of the powder since the amount of heat applied to the powder increases. Further, since the amount of film deposition is controlled by adjusting a transfer speed of the powder, it is difficult to maintain a constant supply amount (concentration) of a source gas onto the base body 60.

Patent Document 1: Japanese Laid-open Publication No. H10-330920 (see Paragraph Nos. 0036 to 0037 and FIG. 1)

### BRIEF SUMMARY OF THE INVENTION

In view of the foregoing, the present disclosure is conceived to provide a source gas generating device capable of producing a film forming source gas by vaporizing a liquid source produced by liquefying a solid source while suppressing its degradation or deterioration, and also capable of obtaining the source gas stably for a long time. Further, the present disclosure also provides a film forming apparatus capable of stably performing a film forming process using the source gas generating device.

In accordance with one aspect of the present invention, there is provided a source gas generating device that generates a film forming source gas by liquefying a solid source into a liquid source and vaporizing the liquid source, the device including: a liquid accommodation unit that accommodates therein the liquid source obtained by liquefying the solid source; a first energy feed unit that supplies energy to raise a temperature of a first region within the liquid accommodation unit to a melting point of the solid source; a second energy feed unit that supplies energy to raise a temperature of a second region within the liquid accommodation unit to a temperature higher than the temperature of the first region, the second region being distanced apart from the first region via a liquid flowing region; a solid source feed unit that supplies the solid source into the first region of the liquid accommodation unit; and an outlet port that discharges the source gas produced by the evaporation of the liquid source within the second region of the liquid accommodation unit.

It is desirable that the source gas generating device includes a liquid surface detector that detects a liquid surface level within the liquid accommodation unit; and a control unit that controls a supply operation of the solid source in the solid source feed unit based on a detection result of the liquid surface detector. Further, in the source gas generating device, it is desirable that a volume of liquid in the first region is larger than a volume of liquid in the second region. It is desirable that the first and second regions are distanced apart from each other in a horizontal direction, and a ceiling surface of the liquid flowing region is lower than a ceiling surface of the second region so as to allow the liquid flowing region to be filled with the liquid source. In this case, it is desirable that a volume of liquid in the first region is larger than a volume of liquid in the second region, and a bottom surface of the first region is lower than a bottom surface of the second region.

In accordance with another aspect of the present invention, there is provided a film forming apparatus that performs a film formation by liquefying a solid source into a liquid source and supplying a source gas, which is produced by vaporizing the liquid source, onto a surface of a substrate, the apparatus including: the source gas generating device; a processing chamber having therein a mounting table configured to mount the substrate thereon; and a gas supply line that supplies the source gas discharged from the outlet port of the source gas generating device onto the surface of the substrate on the mounting table.

In accordance with the present disclosure, when the film forming source gas is produced by liquefying the solid source and vaporizing the liquid source, the liquid accommodation unit for accommodating the liquid source obtained by liquefying the solid source is divided, via the liquid flowing region, into the region (first region) to be supplied with the solid source and the region (second region) for vaporizing the liquid source therein to thereby obtain the source gas. To be specific, in the second region, the liquid source is given high energy so as to generate as much source gas as necessary for the film forming process, whereas in the first region, the liquid source is given energy just necessary for melting the solid source so as to produce the liquid source while suppressing thermal degradation thereof. Therefore, since high heat energy can be applied to only the necessary amount of liquid source, not to the total amount of liquid source used in the film forming process for the plurality of substrates, and since the first region is continuously replenished with the solid source while suppressing a temperature decrease of the liquid source within the second region, it is possible to obtain a predetermined amount of source gas over a long time while suppressing degradation or deterioration of the source. Further, by performing the film forming process while using the source gas produced from the second region, there is no need to stop the film forming process in order to supply the solid source into the liquid accommodation unit. Accordingly, it is possible to perform the film forming process with high throughput.

### BRIEF DESCRIPTION OF THE DRAWINGS

The disclosure may best be understood by reference to the following description taken in conjunction with the following figures:

FIG. 1 is a longitudinal cross-sectional view showing an example of a film forming apparatus in accordance with the present disclosure;

FIG. 2 is an overall configuration view illustrating an example source gas generating device of the film forming apparatus;

FIG. 3 is a plane view illustrating the source gas generating device;

FIG. 4 is a schematic diagram for describing an operation of the source gas generating device;

FIG. 5 is a schematic diagram for describing an operation of the source gas generating device;

FIGS. 6A and 6B are schematic configuration views illustrating another example of the film forming apparatus;

FIG. 7 is a schematic configuration view illustrating still another example of the film forming apparatus; and

FIG. 8 is a longitudinal cross sectional view illustrating still another example of the film forming apparatus.

### DETAILED DESCRIPTION OF THE INVENTION

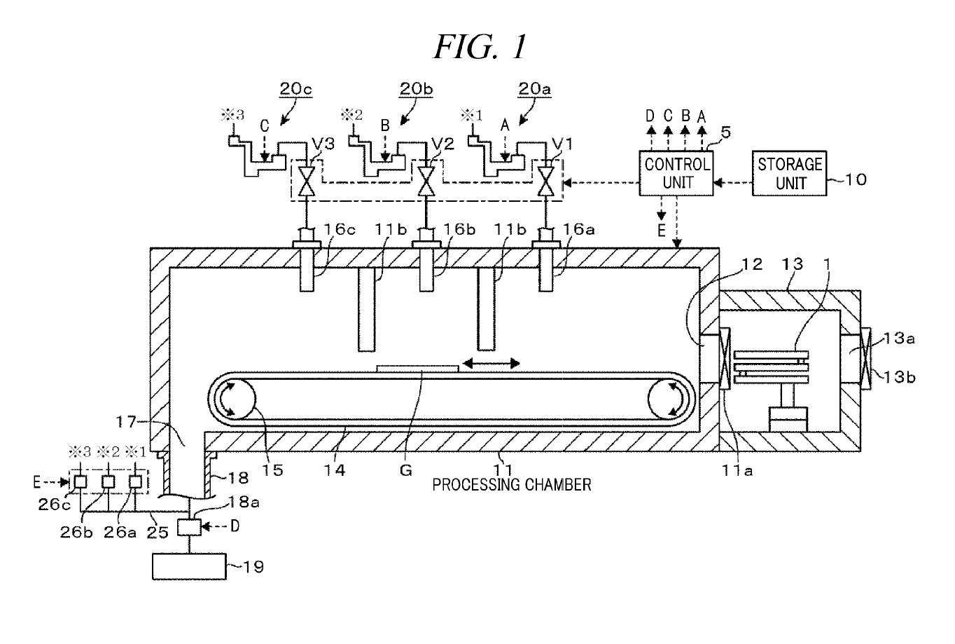

A film forming apparatus using a source gas generating device in accordance with the present disclosure will be explained with reference to FIG. 1. The film forming apparatus is an evaporating apparatus that has been conventionally utilized to form a film by vapor deposition. The film forming apparatus includes, as illustrated in FIG. 1, a processing chamber 11 maintained under a vacuum atmosphere; and a load lock transfer chamber 13 hermetically connected to the processing chamber 11 via a transfer port 12 and having an arm 1 configured to transfer a substrate G between the atmosphere and the processing chamber 11. In FIG. 1, a reference numeral 13a denotes an opening, and reference numerals 11a and 13b represent gate valves.

A substrate transfer mechanism 14 such as a belt conveyor is installed on a bottom surface of the processing chamber 11 by being held on a non-illustrated supporting member. The substrate transfer mechanism 14 serves as a mounting table for mounting thereon, e.g., a substrate for FPD (Flat Panel Display), such as a rectangular glass substrate having a size of about 730 mm×920 mm. The substrate transfer mechanism 14 is configured to be capable of horizontally transferring the substrate G between a position adjacent to the transfer port 12 and a position adjacent to the processing chamber 11's inner wall facing the transfer port 12 by being driven by a driving mechanism 15. Further, the substrate transfer mechanism 14 is provided with a non-illustrated elevating mechanism serving to move, at the position adjacent to the transfer port 12, the substrate G up and down between a position on the substrate transfer mechanism 14 and a lateral position of the transfer port 12. The substrate G is transferred between the processing chamber 11 and the load lock transfer chamber 13 by the elevating mechanism and the arm 1 within the load lock transfer chamber 13.

Further, in the processing chamber 11, there are installed a plurality of, e.g., three gas feed lines 16a to 16c, and they are vertically elongated from a ceiling wall of the processing chamber 11 so as to face a transfer path along which the substrate G is transferred by the substrate transfer mechanism 14 in horizontal direction. One ends of the gas feed lines 16a to 16c are opened while being equi-spaced from each other in sequence from the transfer port 12 along the transfer direction of the substrate G. Other ends of the gas feed lines 16a to 16c are configured to hermetically penetrate the ceiling wall of the processing chamber 11, and they are coupled to source gas generating devices (vaporizing devices) 20a to 20c to be described later via a gas supply mechanism including valves V1 to V3 and the like, respectively. The source gas generating devices 20a to 20c are prepared to form different kinds of multilayered thin films, e.g., three-layered thin films in the present embodiment, on the substrate G. Further, plate-shaped partition walls 11b, for example, are installed between opening ends of the gas feed lines 16a to 16c within the processing chamber 11 in order to suppress mixing of processing gases respectively fed from the gas feed lines 16a to 16c. Further, branch lines (not shown), each having a valve, are connected between the valves V1 to V3 and the source gas generating devices 20a to 20c, respectively. When the supply of the processing gases into the processing chamber 11 is stopped, the valves V1 to V3 are closed, and the processing gases are exhausted through the branch lines.

An exhaust port 17 is opened in a bottom surface of the processing chamber 11, and an exhaust pipe 18 is extended from the exhaust port 17. Further, an evacuation unit 19 including a vacuum pump is connected with the exhaust pipe 18 via a pressure control valve 18a serving as a pressure control unit. Further, as will be described later, one end of a branch pipe 25 is connected to the exhaust pipe 18 upstream (on the side of the processing chamber 11) of the pressure control valve 18a. The other end of the branch pipe 25 is further branched in three, and they are connected to the source gas generating devices 20a to 20c via the pressure control valves 26a to 26c as the pressure control unit, respectively.

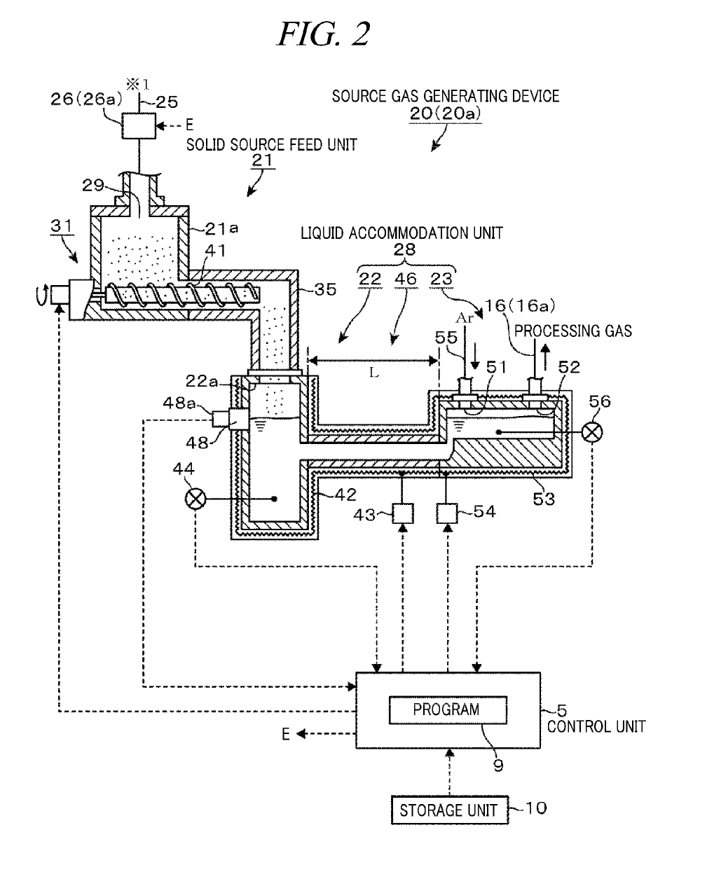

Now, a source gas generating device 20 (20a to 20c) in accordance with the present disclosure will be discussed. Since the respective source gas generating devices 20a to 20c have the same configuration, only the source gas generating device 20a will be explained as the source gas generating device 20, representative of the rest. As illustrated in FIG. 2, the source gas generating device 20 includes a solid source feed unit 21 that supplies a solid source; and a liquid accommodation unit 28 that produces a liquid source by melting the solid source fed from the solid source feed unit 21 and obtains a source gas by evaporating the liquid source.

The solid source feed unit 21 includes a hermetically sealed storage vessel 21a that stores the solid source therein at, e.g., a normal temperature; and a screw feeder 31 horizontally installed at a bottom portion of the storage vessel 21a to supply a preset amount of solid source. The solid source may be, e.g., a powdered organic material, such as a low-molecular-weight aryl amine derivative, for forming an EL (Electro Luminescence) material film. An exhaust port 29 is formed in a top surface of the storage vessel 21a, and the branch pipe 25 extended from the above-mentioned pressure control valve 26(26a) is connected to the exhaust port 29. The inside of the storage vessel 21a (specifically, the gas within the storage vessel 21a and within a first liquid tub 22 to be described later) is evacuated by the above-mentioned evacuation unit 19 through the exhaust port 29, whereby liquid surfaces of the first liquid tub 22 and a second liquid tub 23 become to have substantially same height, as will be discussed later. The source gas generating devices 20b and 20c store therein, e.g., an iridium complex and an alumiquinolinol complex as solid sources, respectively.

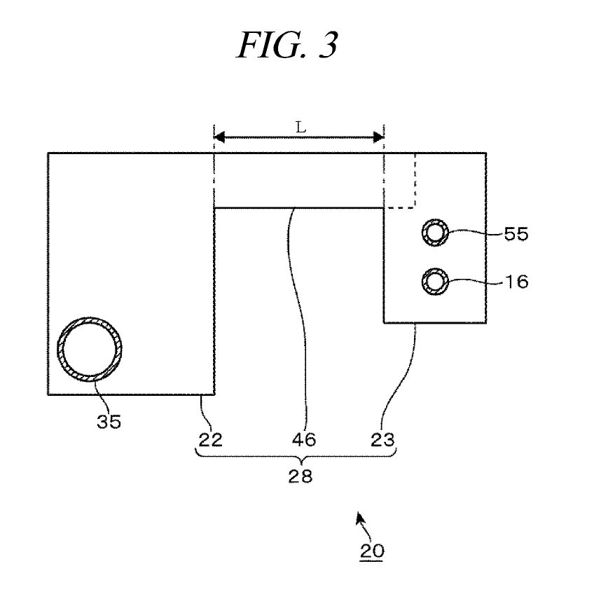

A liquid accommodation unit 28 is installed below the solid source feed unit 21, and it includes the first liquid tub 22 having, e.g., a rectangular parallelepiped shape and forming a first region; the second liquid tub 23 having, e.g., a rectangular parallelepiped shape and spaced apart from the first liquid tub 22 in horizontal direction and forming a second region; and a communication passage 46 forming a liquid flowing region through which the first liquid tub 22 and the second liquid tub 23 are allowed to communicate with each other. The communication passage 46 is located at a middle position of the first liquid tub 22 in height direction. Further, referring to FIG. 3, in a plane view, the communication passage 46 is connected to a position close to one of the four corners of the first liquid tub 22, and is made of a rectangular pipe elongated sideways. The first liquid tub 22 has a ceiling surface 22a, and a lower end of a vertically elongated column serving as a solid source feed line 35 is hermetically connected to a ceiling surface 22a's corner portion diagonally facing the above-mentioned corner. Upper end of the solid source feed line 35 is vertically extended and horizontally bent toward a sidewall of the above-stated solid source feed unit 21 in an L-shape. Further, provided at a leading end of the solid source feed line 35 is an outlet port for the solid source feed unit 21, i.e., a supply port 41 for the liquid accommodation unit 28. Accordingly, the solid source fed from the solid source feed unit 21 is discharged to the outlet port (supply port 41) by the screw feeder 31 and falls down into the first liquid tub 22 to be supplied therein.

In the present embodiment, the first liquid tub 22 is installed such that its bottom surface is located lower (deeper) than the bottom surface of the second liquid tub 23. The second liquid tub 23 generates a source gas by heating and evaporating the liquid source therein. Further, the second liquid tub 23 is configured to have a shallow depth so as to minimize the amount of liquid source contained and heated therein to thereby suppress thermal degradation and to have a large surface area so as to enlarge an evaporation surface to thereby maximize an evaporation amount. A ceiling surface of the second liquid tub 23 is positioned higher than a ceiling surface of the communication passage so as to prevent the source gas generated within the second liquid tub 23 from flowing into the communication passage 46. Further, the ceiling surface of the second liquid tub 23 is positioned lower than the ceiling surface of the first liquid tub 22 so as to allow a liquid surface height detector 48a, which will be described later, to detect a liquid surface level within the second liquid tub based on a liquid surface level of the liquid source within the first liquid tub 22. Furthermore, since the inside of the solid source feed unit 21 is evacuated, the gas within both of the first liquid tub 22 and the second liquid tub 23 is exhausted. Thus, even if there is a pressure difference between the first and second tubs 22 and 23, the difference would be small, so that their liquid surface levels become almost same.

A first heater 42 serving as a first energy feed unit is installed to surround the first liquid tub 22 to melt the solid source supplied from the supply port 41 while suppressing thermal degradation thereof. The heater 42 heats the solid source supplied from the supply port 41 to a temperature of, e.g., about 280° C. to about 285° C., desirably, about 280° C., which is close to a melting point of the solid source but higher than it by, e.g., about 5° C. to about 10° C., desirably about 5° C. The heater 42 is connected to a power supply 43.

Further, a temperature detector 44 having, e.g., a thermocouple is provided to the first liquid tub 22 so as to detect a temperature of a liquid source produced by melting the solid source. A heat amount of the heater 42 is controlled through the power supply 43 by a control unit 5 to be described later based on a detected temperature value of the temperature detector 44.

Further, as in the case of the first liquid tub 22, the heater 42 is also installed to surround the communication passage 46 so as to prevent the liquid source flowing within the communication passage 46 from being cooled and solidified. A length L of the communication passage 46 is set so as to suppress a temperature decrease of the second liquid tub 23 when the liquid source is supplied from the first liquid tub 22 to the second liquid tub 23. That is, the length L is set so as to stabilize the liquid source at a preset temperature as the liquid source approaches the second liquid tub 23 while flowing through the communication passage 46. Further, the length L is set so as to prevent a backflow of the high-temperature liquid source from the second liquid tub 23 due to diffusion. Moreover, a transparent window 48 made of a transparent material such as quartz is installed at, e.g., the first liquid tub 22's sidewall portion facing the communication passage 46 so as to be located higher than the ceiling surface of the communication passage 46. The liquid surface height within the first liquid tub 22 is detected via the transparent window 48 by the liquid surface height detector 48a, which serves as an external liquid surface detecting unit.

The liquid surface height detector 48a includes, for example, laser beam emitter/receiver arranged in multiple height positions. Based on reflection light of the respective laser beams, the liquid surface height detector 48a detects which light is reflected from liquid so that it detects a height of the liquid surface. When the liquid surface level detected by the liquid surface height detector 48a is below a preset level, the control unit 5 to be described later outputs a control signal to the solid source feed unit 21, so that the solid source feed unit 21 performs a supply operation for a certain time, i.e., supplies a preset amount of solid source into the first liquid tub 22 by rotating the screw feeder 31. The above method of controlling the supply of the solid source based on the height of the liquid surface may be also implemented by performing the supply operation until a preset upper-limit liquid surface level is detected after a lower-limit liquid surface level is detected. Further, besides such an optical method, for example, a liquid surface detecting system such as a limit switch that detects a liquid surface height electrically may be employed, as the liquid surface height detector 48a.

A second heater 53 serving as a second energy feed unit is installed to surround the second liquid tub 23 so as to heat the liquid source within the second liquid tub 23 to a temperature higher than the above-specified temperature of the liquid source in the first liquid tub 22, e.g., about 300° C. to about 350° C., desirably, about 320° C. The heater 53 is connected to a power supply 54. Accordingly, a difference between the heating temperature for the liquid source in the second liquid tub 23 and the heating temperature for the liquid source in the first liquid tub 22 ranges from about 20° C. to about 65° C.

Further, a temperature detector 56 such as a thermocouple is provided to the second liquid tub 23. A heat amount (heating temperature for the liquid source) of the heater 53 is controlled by the control unit 5 through the power supply 54 based on a detected temperature value of the temperature detector 56. For example, it is controlled to, e.g., the above-mentioned heating temperature ±0.05° C. or thereabout.

A carrier gas inlet port 51 and a gas outlet port 52 are provided in the ceiling surface of the second liquid tub 23. A carrier gas such as an argon (Ar) gas is flown from the carrier gas inlet port 51 into a region between the surface of the liquid source and the ceiling surface of the second liquid tub 23. This carrier gas and a source gas evaporated from the surface of the liquid source are supplied into the above-described film forming apparatus through the gas outlet port 52 as a processing gas. A carrier gas supply source (not shown) is connected to a carrier gas supply line 55 extended from the carrier gas inlet port 51 via a valve (not shown) or a flow rate controller (not shown). Further, the above-described gas feed line 16 (16a to 16c) is connected to the gas outlet port 52. A non-illustrated heater is installed around the gas feed line 16 so as to heat the processing gas to, e.g., about 300° C., thus preventing solidification of the source gas in the processing gas flowing through the gas feed line 16.

The above-described control unit 5 is installed in this film forming apparatus, as illustrated in FIGS. 1 and 2. For example, the control unit 5 is configured as, e.g., a computer including CPU, a memory, a working memory (all of these are not illustrated) and a program 9. For example, for each of the source gas generating devices 20a to 20c, the heating temperature for the liquid source (output values of the power supplies 43 and 54), a flow rate of the carrier gas, a transfer speed of the substrate G by the substrate transfer mechanism 14, and the like are stored in this memory. Further, the program 9 includes commands to read out recipes from the memory and to output control signals to each component of the film forming apparatus. Thus the program 9 performs a film forming process to be described later on the substrate G by controlling power supplied to the heaters 42 and 53 from the power supplies 43 and 54 based on the temperature values of the liquid source in the first and second liquid tubs 22 and 23 detected by the temperature detectors 44 and 56, respectively. Further, the program 9 performs a start and a stop of the supply of the solid source into the first liquid tub 22 (rotation and stop of the screw feeder 31) based on a detection result of the surface level of the liquid source obtained by the liquid surface height detector 48a for each of the source gas generating devices 20a to 20c. The program 9 is stored in a storage unit 10 such as a hard disk, a compact disk, a magnet optical disk, a memory card, or the like and is installed in the computer.

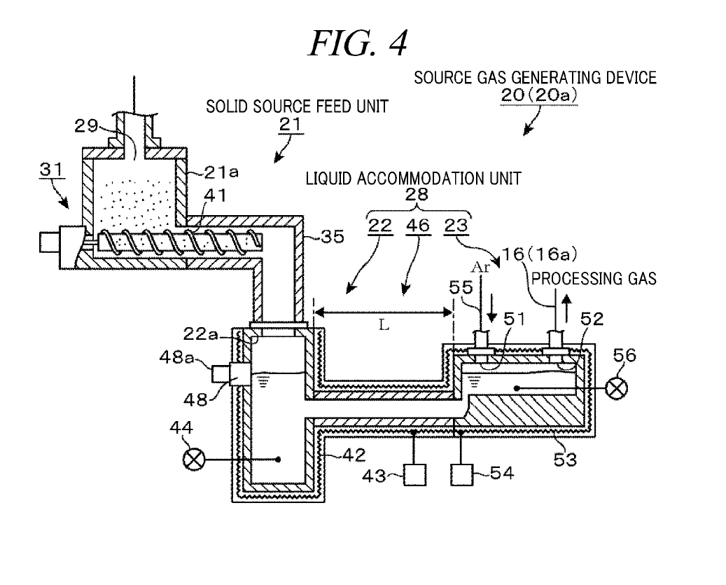

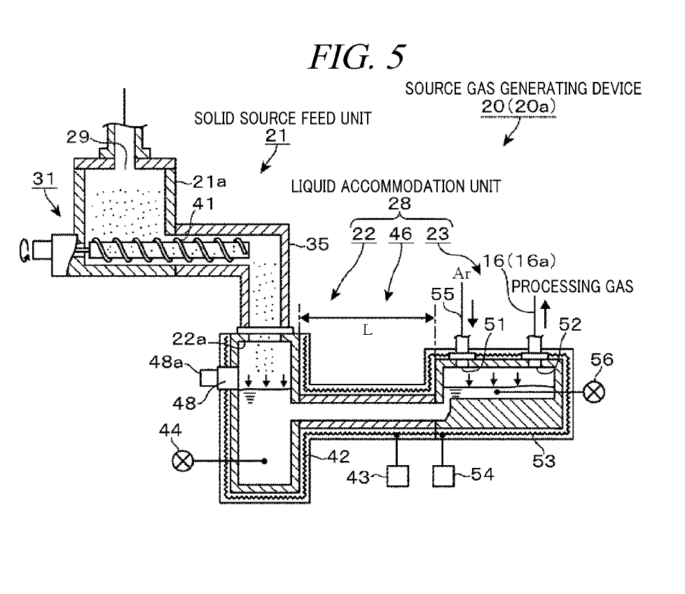

Now, an operation of the film forming apparatus configured as described above will be explained with reference to FIGS. 4 and 5. First, generation of the source gas in the source gas generating device 20 will be described for the state that the solid source is already supplied and the source gas is being generated. A preset amount of solid source is already stored in the solid source feed unit 21. The solid source supplied from the solid source feed unit 21 is being melted in the first liquid tub 22, and the liquid source is being generated therein, as illustrated in FIG. 4. Since the solid source is gradually heated in the first liquid tub 22 to the temperature higher than and close to the melting point of the solid source as stated above, the temperature within the first liquid tub 22 is maintained lower than a temperature at which thermal degradation or deterioration of the solid source may occur. Thus, degradation or deterioration of the solid source is suppressed. Furthermore, since the heating temperature in the first liquid tub 22 is low, a generation amount of the source gas is small even if the source gas is generated within the first liquid tub 22. Further, since the source gas, if any, is cooled and solidified on, e.g., the inner wall of the solid source feed line 35 when it rises toward the solid source feed unit 21, the amount of the source gas reaching the solid source feed unit 21 is very small.

As mentioned above, in the first liquid tub 22, since the liquid surface height is higher than the ceiling surface of the communication passage 46, the liquid source melted in the first liquid tub 22 is made to flow toward the second liquid tub 23 while filling the communication passage 46 from top to bottom. Here, the amount of the liquid source flowing toward the second liquid tub 23 depends on an evaporation amount of the liquid source in the second liquid tub 23. In the second liquid tub 23, since the liquid source is heated to the heating temperature higher than that in the first liquid tub 22, the liquid source in the communication passage 46 is more strongly heated as it approaches the second liquid tub 23. Therefore, there is generated a temperature gradient so that the temperature increases slowly in a communication passage 46's region close to the second liquid tub 23 or the temperature increases slowly from the first liquid tub 22 toward the second liquid tub 23.

In the second liquid tub 23, the source gas, heated and generated by evaporation of the liquid source, stays in the region between the surface of the liquid source and the ceiling surface of the second liquid tub 23. The source gas is flown toward the processing chamber 11 through the gas outlet port 52 as a processing gas along with the carrier gas which is supplied from the carrier gas inlet port 51 at a preset flow rate. Here, since the inside of the communication passage 46 is always filled with the liquid source from top to bottom as mentioned above, the area of an evaporation region, i.e., a source gas generation area is uniformed. Further, since the temperature of the liquid source within the second liquid tub 23 is regulated as discussed above, a generation amount of the source gas is stabilized. Moreover, when the film forming process is not performed on the substrate G, e.g., when loading/unloading of the substrate G into/from the processing chamber 11 is performed, the valve V is closed, for example, whereby the processing gas is discharged to the outside of the system through a non-illustrated branch line provided in the gas feed line 16.

Here, since the surface heights of the liquid source within the first and second liquid tubs 22 and 23 are substantially same, the liquid surface level within the second liquid tub 23 can be detected by the liquid surface height detector 48a. If the surface level of the liquid source is lowered than, e.g., a lower-limit liquid surface level, the screw feeder 31 rotates for a certain period of time or until the liquid surface level reaches an upper-limit liquid surface level, whereby the solid source is supplied from the solid source feed unit 21 into the first liquid tub 22 in a preset amount or until the surface height of the liquid source exceeds a laser beam irradiation height. At this time, the temperature of the liquid source within the first liquid tub 22 slightly decreases due to the replenishment of the solid source of normal temperature. Since, however, the length L of the communication passage 46 is set sufficiently long, the temperature of the liquid source would rise to the substantially same level as the temperature of the liquid source within the second tub 23 by the time when it reaches the second liquid tub 23. As a result, a temperature decrease of the liquid source within the second liquid tub 23 is suppressed.

As described above, since the solid source is inputted even when the source gas is being supplied, the space in which the source gas stays does not decrease during the film forming process or between a plurality of substrates G on which the film forming process is performed. Accordingly, since nonuniform distribution of the source gas in that space is suppressed, for example, the source gas and the carrier gas supplied into the second liquid tub 23 can be mixed uniformly. Thus, the amount of the source gas supplied toward the processing chamber 11 as the processing gas (the concentration of the source gas in the processing gas) is maintained almost constant over a long period of time when the film formation on the plurality of substrates G is performed.

Now, an example film forming process, which is performed on a substrate G using the source gas generated as described above, will be explained. First, the substrate G is loaded into the load lock transfer chamber 13 from outside. Then, after the inside of the load lock transfer chamber 13 is evacuated to a preset vacuum level by the non-illustrate vacuum pump, the gate valve 11a is opened, and the substrate G is mounted on the substrate transfer mechanism 14 within the processing chamber 11 which is maintained at a preset vacuum level by evacuation unit 19. Subsequently, the valves V1 to V3 are opened, and individual source gases, e.g., a low-molecular-weight aryl amine derivative, an iridium complex and an alumiquinolinol complex are supplied into the processing chamber 11 in preset concentrations along with carrier gases via the gas feed lines 16a to 16c, respectively, as processing gases. Then, the inside of the processing chamber 11 is regulated at a preset vacuum level. Subsequently, the substrate G is transferred to the left by the substrate transfer mechanism 14 at a certain transfer speed. The source gases supplied to the substrate G are adsorbed onto the substrate G and solidified thereon, thus forming thin films. Thus, as the substrate G is moved through respective processing regions below the gas feed lines 16a to 16c from right to the left by the substrate transfer mechanism 14, the source gases of, e.g., different kinds supplied from the respective gas feed lines 16a to 16c are sequentially solidified, thereby forming thin films. As a result, a three-layered film is formed on the substrate G.

Thereafter, the valves V1 to V3 are closed, whereby the processing gases are flown to non-illustrated branch lines. Further, the processing gas is discharged by evacuating the processing chamber 11, and the substrate G is unloaded from the film forming apparatus in the reverse sequence as it is loaded. Then, a next unprocessed substrate G is loaded into the processing chamber 11, and after opening the valves V1 to V3, the same film forming process is performed on the substrate G in sequence. In this way, the film forming process is performed on a plurality of substrates G. When the surface height of the liquid source within the first liquid tub 22 (second liquid tub 23) is lowered, the solid source is supplied into the first liquid tub 22 as stated above, and the liquid source is replenished into the second liquid tub 23. In this way, the film forming process can be performed on the plurality of substrates G continuously without interruption for supplying the solid source.

In accordance with the embodiment as described above, to produce the film forming source gas by evaporating the solid source, there are installed the solid source feed unit 21 storing the solid source therein, the first liquid tub 22 for producing the liquid source by melting the solid source supplied from the solid source feed unit 21 and the second liquid tub 23 for producing the source gas by evaporating the liquid source flown from the first liquid tub 22. In the second liquid tub 23, the source gas is generated by heating the liquid source to a high temperature so as to obtain a necessary amount gas for the film formation, whereas, in the first tub 22, the liquid source is produced by heating the solid source to a relatively low temperature suitable for melting the solid source, thus suppressing thermal degradation. The produced liquid source is flown from the first liquid tub 22 to the second liquid tub 23. With this configuration, since a large amount of heat can be applied only to a necessary amount of liquid source, not to the total amount of it, and since the solid source can be continuously replenished into the first liquid tub 22 while suppressing a temperature decrease of the liquid source within the second liquid tub 23, a constant amount of source gas can be obtained over a long period of time without degradation or deterioration of the source. Moreover, since variation of the space in which the source gas stays within the second liquid tub 23 (region between the surface of the liquid source and the ceiling surface of the second liquid tub 23) is suppressed while the film forming process is being performed on the plurality of substrates G, the source gas and the carrier gas can be mixed uniformly and the supply amount of the source gas can be stabilized, for example. As stated above, when the liquid source is fed into the second liquid tub 23, since the length L of the communication passage 46 is long, the temperature of the liquid source can be stabilized. That is, since the liquid source flows through the communication passage 46 and the temperature of the liquid source increases to the substantially same level as the temperature of the liquid source within the second liquid tub 23, a temperature decrease of the liquid source within the second liquid tub 23 can be suppressed.

Furthermore, although the temperature of the liquid source within the second liquid tub 23 needs to be accurately controlled to obtain the constant amount of the source gas over the long period of time, it is sufficient to roughly control the temperature of the liquid source within the first liquid tub 22. Thus, the temperature can be more easily controlled as compared to, e.g., a case of controlling the temperature of the total amount of liquid source, which is used for the plurality of substrates G on which the film formation is performed, in both of the first and second liquid tubs 22 and 23. Furthermore, when the liquid source is supplied into the second liquid tub 23, the liquid source is made to flow toward the second liquid tub from the first liquid tub 22 spontaneously due to the evaporation of the liquid source in the second liquid tub 23 or due to the supply of the solid source into the first liquid tub 22 as described above. Thus, a component such as a high-price valve having a resistance against a high temperature need not be installed at the communication passage 46 to be used for the start and stop of the supply of the liquid source or control of its flow rate. Thus, the film forming apparatus can be simplified and thus can be manufactured cost-effectively.

Moreover, since the film forming process is performed using the source gas discharged from the second liquid tub 23, the film forming process need not be stopped to supply the solid source into the second liquid tub 23. Thus, the film forming process can be carried out with high throughput. Furthermore, since the constant amount of source gas can be generated over the long period of time, thin film thicknesses can be uniformed between the plurality of substrates G on which the film forming process is performed. Accordingly, even when the amount of the source gas necessary for the film formation increases due to the scale-up of the substrates G up to, e.g., about 3000 mm×3320 mm, the film forming process can be stably performed continuously.

In the above-described embodiment, although the plurality of source gas generating devices 20a to 20c are installed to form the different kinds of thin films, it may be possible to form a same kind of thin films or to install only a single source gas generating device 20. In such a case, there can be employed a configuration in which the plurality of substrates G are loaded into the processing chamber 11 at one time, and the film forming process is performed on these substrates G at the same time.

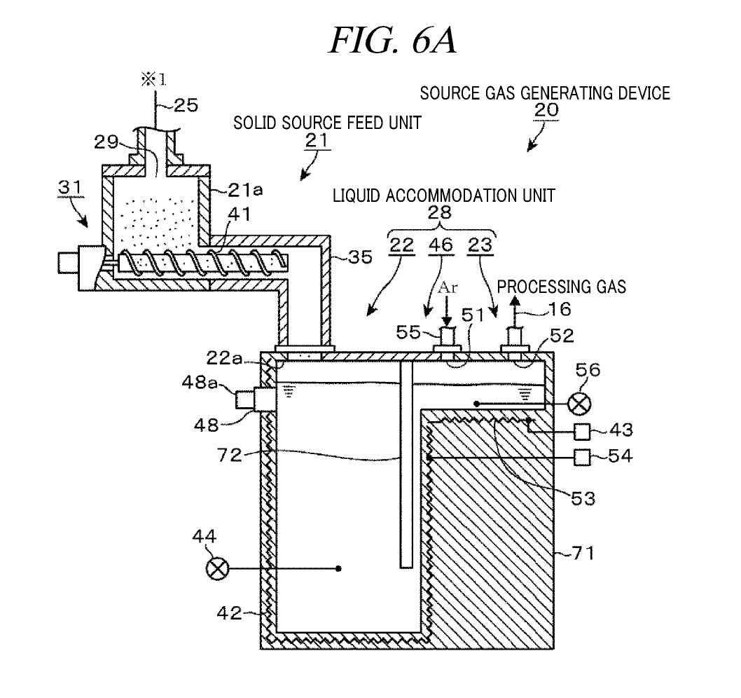

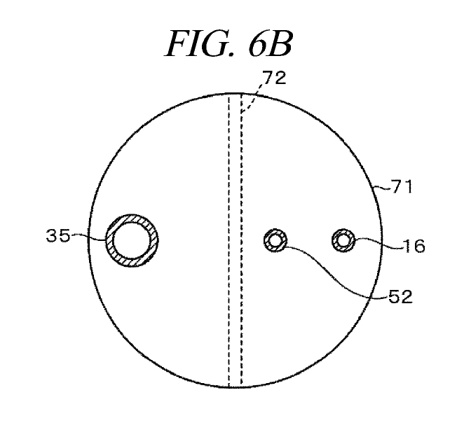

In the above-described source gas generating device 20, although the first liquid tub 22 and the second liquid tub 23 are distanced apart from each other via the horizontally elongated communication passage 46, the communication passage 46 may be vertically elongated. In this case, a first liquid tub 22 and a second liquid tub 23 may be installed within a vacuum chamber 71 having, e.g., a cylinder shape, as shown in FIGS. 6A and 6B. To elaborate, a vertical wall 72 is installed at an approximately central position of the vacuum chamber 71 to be extended vertically between a ceiling surface of the vacuum chamber 71 and a position adjacent to a bottom surface thereof. The vacuum chamber 71 is divided in left and right regions by the vertical wall 72, and the first liquid tub 22 is formed in one of them (left side) and the second liquid tub 23 is formed in the other (right side). A bottom surface of the second liquid tub 23 is located high at a position adjacent to a liquid surface stored in the vacuum chamber 71 and the bottom surface ranges from a position adjacent to the vertical wall 72 to the sidewall of the second liquid tub 23. By this configuration, a communication passage 46 is provided between the second liquid tub 23 and the vertical wall 72.

In this source gas generating device 20 having such a configuration, the source gas can be generated and the film forming process can be performed in the same manner as described in the above embodiment, so that the same effect can be achieved. Furthermore, in FIGS. 6A and 6B, same parts as those described in FIG. 2 will be assigned same reference numerals, and thus redundant description thereof will be omitted.

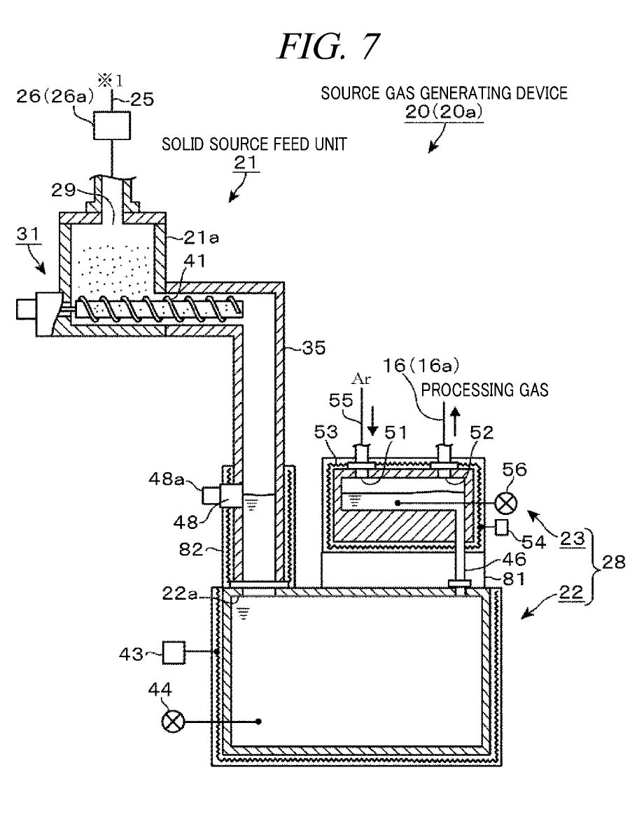

Moreover, when such a vertical communication passage 46 is formed, it may be possible to elongate a first liquid tub 22 in horizontal direction, install a second liquid tub on top of the first liquid tub 22 via, e.g., a heat insulating member 81 and form a communication passage 46 downward from the second liquid tub 23, as illustrated in FIG. 7. In this example, the source gas can be generated and the film forming process can be carried out, thus achieving the same effect as in the above-described examples. In FIG. 7, a reference numeral 82 is a heater that heats the solid source to a temperature higher than and close to the melting point thereof, and a liquid surface is detected in the solid source feed line 35. Further, in FIG. 7, same parts as those described in FIG. 2 will be assigned same reference numerals, and thus redundant description thereof will be omitted.

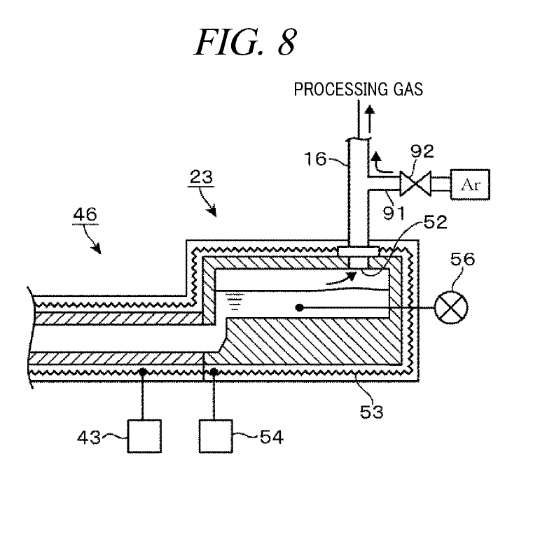

Further, in the above-described embodiment, although the carrier gas is supplied into the second liquid tub 23 and then supplied into the processing chamber 11 along with the source gas as the processing gas, it may be possible to introduce the evaporated source gas into the processing chamber 11 by suctioning it with the evacuation unit 19 without supplying the carrier gas, for example. In this case, a carrier gas feed line 91 may be installed at the gas feed line 16, as illustrated in FIG. 8, and the source gas can be supplied into the processing chamber 11 along with a carrier gas supplied from the carrier gas feed line 91 as a processing gas. In FIG. 8, a reference numeral 92 denotes a valve.

Further, although the same heater 42 as in the first liquid tub 22 is installed in the communication passage 46, a different heater may be used, and its temperature can be controlled independently of the heaters 42 and 53. In such a case, the liquid source in the communication passage 46 is heated to, e.g., a certain temperature between the heating temperature of the liquid source in the first liquid tub 22 and the heating temperature of the liquid source in the second liquid tub 23. Further, in this communication passage 46, the heater may be configured in multi-levels so as to control the temperature of the liquid source precisely such that the temperature increases gradually as the liquid source approaches the second liquid tub 23. In addition, as a means (power feed unit) for supplying the solid source into the first liquid tub 22, a device using, e.g., ultrasonic vibration may be employed instead of the screw feeder 31. Further, besides the powder type, the solid source may be in the form of flakes or grains.

Moreover, the present disclosure can also be applied to a case of performing a film formation on, e.g., a roll-type plastic film besides the FPD substrate G. Further, although the heaters 42 and 53 are used as the first and second energy feed units in the present embodiment, an energy feed unit using plasma, laser or the like can be used instead.

What is claimed is:

1. A source gas generating device that generates a film forming source gas by liquefying a solid source into a liquid source and vaporizing the liquid source, the device comprising:
a liquid accommodation unit that accommodates therein the liquid source obtained by liquefying the solid source;
a first energy feed unit that supplies energy to raise a temperature of a first region within the liquid accommodation unit to a melting point of the solid source;
a second energy feed unit that supplies energy to raise a temperature of a second region within the liquid accommodation unit to a temperature higher than the temperature of the first region, the second region being distanced apart from the first region via a liquid flowing region;
a solid source feed unit that supplies the solid source into the first region of the liquid accommodation unit; and
an outlet port that discharges the source gas produced by the evaporation of the liquid source within the second region of the liquid accommodation unit.

2. The source gas generating device of claim 1, further comprising:
a liquid surface detector that detects a liquid surface level within the liquid accommodation unit; and
a control unit that controls a supply operation of the solid source in the solid source feed unit based on a detection result of the liquid surface detector.

3. The source gas generating device of claim 1, wherein a volume of liquid in the first region is larger than a volume of liquid in the second region.

4. The source gas generating device of claim 1, wherein the first and second regions are distanced apart from each other in a horizontal direction, and a ceiling surface of the liquid flowing region is lower than a ceiling surface of the second region so as to allow the liquid flowing region to be filled with the liquid source.

5. The source gas generating device of claim 4, wherein a volume of liquid in the first region is larger than a volume of liquid in the second region, and a bottom surface of the first region is lower than a bottom surface of the second region.

6. A film forming apparatus that performs a film formation by liquefying a solid source into a liquid source and supplying a source gas, which is produced by vaporizing the liquid source, onto a surface of a substrate, the apparatus comprising:
a source gas generating device as claimed in claim 1;
a processing chamber having therein a mounting table configured to mount the substrate thereon; and
a gas supply line that supplies the source gas discharged from the outlet port of the source gas generating device onto the surface of the substrate on the mounting table.
